(19) United States
(12) Patent Application Publication
(10) Pub. No.: US 2023/0247906 A1
(43) Pub. Date: Aug. 3, 2023

(54) MATERIAL DEPOSITION METHOD

(71) Applicant: LUXEMBOURG INSTITUTE OF SCIENCE AND TECHNOLOGY (LIST), Esch-sur-Alzette (LU)

(72) Inventors: Nicolas GODARD, ESCH-SUR-ALZETTE (LU); Sebastjan GLINSEK, ESCH-SUR-ALZETTE (LU); Alfredo BLAZQUEZ MARTINEZ, ESCH-SUR-ALZETTE (LU); Emmanuel DEFAY, Esch-sur-Alzette (LU)

(21) Appl. No.: 18/013,014

(22) PCT Filed: Jun. 25, 2021
(86) PCT No.: PCT/EP2021/067451

§ 371 Date: Dec. 27, 2022

(30) Foreign Application Priority Data
Jun. 26, 2020 (LU) LU 101884

(51) Int. Cl. H10N 30/077; H10N 30/093; H01L 21/02

(52) U.S. Cl. CPC H10N 30/077; H01L 21/02197; H01L 21/02282; H10N 30/093

(57) ABSTRACT

A material deposition method comprising: preparing a precursor solution of Pb(Zrₓ,Ti₁₋ₓ)O₃ using 1-methoxy-2-propanol as a solvent and acetylacetone as a modifier; and forming a seed layer for a electroactive film by spin coating the precursor solution on a substrate. The electroactive film can be PZT, PZO or BFO, spin-coated or inkjet printed on the seed layer. Experience shows pure orientation for the piezoelectric film thanks to the use of 1-methoxy-2-propanol when preparing the seed layer. This orientation is attributed to the formation of nano crystals on the seed layer constituting a pre-crystallization.

### CROSS REFERENCE TO RELATED APPLICATIONS

The present invention is the US national stage under 35 U.S.C. §371 of International Application No. PCT/EP2021/067451 which was filed on Jun. 25, 2021, and which claims the priority of application LU101884 filed on Jun. 26, 2020 the contents of which (text, drawings and claims) are incorporated here by reference in its entirety.

### FIELD

The invention relates to the field of microsystem manufacturing and in particular the manufacturing of electroactive (pyroelectric or piezoelectric or ferroelectric or antiferroelectric or electrostrictive or dielectric) devices obtained by inkjet printing or spin coating deposition on a platinized silicon substrate.

### BACKGROUND

It has been shown that the crystalline orientation of thin films influences the ferroelectric properties of electroactive films such as in piezoelectric devices (Trolier-McKinstry et al., “Thin Film Piezoelectrics for MEMS”, Journal of Electroceramics, vol. 12, pp. 7-17, 2004). The crystalline orientation (100) is particularly preferred.

As for the technique used for thin films deposition, spin coating or inkjet printing have been shown to have some benefits. An example of inkjet printing is given in WO 2020/084066 A1.

However, the literature seems to lack a procedure that enables to reach the orientation (100) for a thin film of Pb(Zr,Ti)O₃, Bi(Fe,Mn,Ti)O₃ or PbZrO₃ that is inkjet printed or spin-coated on a substrate.

### SUMMARY

The present invention addresses the above-mentioned deficiencies and aims at improving the piezoelectric properties of a thin film.

As will be more explained below, the inventors have shown that the use of 1-methoxy-2-propanol as solvent for the preparation of a Pb(Zrₓ,Ti₁₋ₓ)O₃ seed layer enables the thin film of Pb(Zr,Ti)O₃, (PZT), Bi(Fe,Mn,Ti)O₃ (BFO) or PbZrO₃ (PZO) to have predominant crystalline orientation of (100). Among the hundreds of existing solvents, it has been identified that the use of 1-methoxy-2-propanol when preparing the precursor solution of the seed layer has an unexpected and beneficial particular effect on the piezoelectric layer. It has also been identified that using acetylacetone as a modifier further increases these effects. Although acetylacetone is not essential, it may participate to further improve the present method.

Hence, the above-stated problem is solved by a material deposition method comprising: preparing a precursor solution of Pb(Zrₓ,Ti₁₋ₓ)O₃ using 1-methoxy-2-propanol as a solvent and acetylacetone as a modifier; and forming a seed layer for a piezoelectric film by spin coating the precursor solution on a substrate. The precursor solution can consist (exclusively) of Pb(Zrₓ,Ti₁₋ₓ)O₃, 1-methoxy-2-propanol and acetylacetone. According to some advantageous embodiments, the process is carried out without water. The absence of water may avoid or lower any hydrolysis reaction between the reactants, and the solution ages much less than the ones based on water.

The substrate can be of various nature, such as a platinized silicon substrate or a glass substrate.

Advantageously, x=0, and thus the Pb(Zrₓ,Ti₁₋ₓ)O₃ solution is PbTiO₃.

According to various advantageous embodiments, for preparing the precursor, at least some of the following steps are performed: dissolving titanium(IV) isopropoxide in anhydrous 1-methoxy-2-propanol; adding acetylacetone, in various instances two molar equivalents to Ti precursor of acetylacetone; stirring this titanium precursor solution, for example for 15 minutes at room temperature; adding freeze-dried lead(II) acetate; heating for dissolving lead(II) acetate; refluxing and optionally distilling; and diluting to 0.1 mol/L using anhydrous 1-methoxy-2-propanol.

According to various advantageous embodiments, 1-methoxy-2-propanol is dried with 3 Å zeolite molecular sieves prior to use. Besides, some other known means can be used to dry the 1-methoxy-2-propanol, to drastically deplete it from water, in order to avoid, for example, any unwanted ageing of the reactants.

According to various advantageous embodiments, the step of spin coating the seed layer comprises: spin coating at a first rotational speed for a first duration; and then spin coating at a second rotational speed, greater than the first speed, for a second duration, longer than the first duration. These two steps deposition process guarantees the obtention of a more uniform film or layer on the substrate. The thickness is essentially the same all over the substrate, for example the thickness variation all over the substrate is in various instances less than 10%, for example of from 10% to 5%, or better less than 5%.

According to various advantageous embodiments, after deposition of the seed layer, the seed layer can be dried, in various instances at temperatures of from 100° C. to 150° C., for example at about 130° C., for 3 minutes, pyrolyzed, in various instances at temperatures of from 300° C. to 400° C., for example at about 350° C. for 3 minutes, and crystallized, in various instances temperatures of from 650° C. to 750° C., for example at about 700° C. for 1 minute.

In some advantageous embodiments, the method can further include depositing a piezoelectric film or layer onto the seed layer, although the technical effect can already be obtained without the necessary need of the piezoelectric layer.

The deposited piezoelectric layer onto the seed layer can advantageously be formed of a compound selected from the group consisting of Pb(Zr,Ti)O₃, PbZrO₃, BaTiO₃, SrTiO₃, (Ba,Sr)TiO₃, Pb(Mg,Nb)-PbTiO₃, BiFeO₃, (K,Na)NbO₃, PbTiO₃, Pb(Zr,Ti)O₃ doped with La, Mn or Nb, and Pb(Sc,Ta)O₃, or mixture(s) thereof.

The deposition of material on the seed layer can be made by inkjet printing, spin-coating, sputtering, Pulsed Laser Deposition, MOCVD, etc. In such a case, the layer exhibits an (100) orientation.

According to various advantageous embodiments, the method comprises, before depositing the piezoelectric layer, preparing a solution for the piezoelectric layer of perovskite structures compound, wherein the compound is such as selected from the group consisting of Pb(Zr,Ti)O₃, Bi(Fe,Mn,Ti)O₃, PbZrO₃, PbTiO₃ and doped-Pb(Zr,Ti)O₃, or mixture(s) thereof, the concentration of the solution is between 0.1 and 2 mol/L in a solvent of 1-methoxy-2-propanol or 2-methoxyethanol. In such a case, the layer exhibits an (100) orientation.

According to various advantageous embodiments, the method can further comprise diluting the solution of one selected from the group consisting of Pb(Zr,Ti)O₃, Bi(Fe,Mn,Ti)O₃, PbZrO₃, PbTiO₃ and doped-Pb(Zr,Ti)O₃ to 0.4 M with 1,3-propanediol or glycerol or ethyleneglycol, and mixture thereof, and depositing the diluted solution by inkjet printing on the seed layer.

According to various advantageous embodiments, the method comprises, before depositing the piezoelectric layer, preparing a solution of BiFeO₃ which can optionally be doped with Mn and/or Fe, with a concentration of from 0.1 mol/L and 2 mol/L, in various instances 0.25 mol/L, in a solvent of 1-methoxy-2-propanol or 2-methoxyethanol. In such a case, the layer exhibits an (100) orientation. The step of depositing the piezoelectric layer can consist in spin coating the solution of BiFeO₃ on the seed layer.

According to various advantageous embodiments, the step of depositing the piezoelectric layer consists in spin coating the solution of one selected from the group consisting of Pb(Zr,Ti)O₃, Bi(Fe,Mn,Ti)O₃, PbZrO₃, PbTiO₃, doped-Pb(Zr,Ti)O₃ and BiFeO₃ on the seed layer.

According to various advantageous alternate embodiments, the method can comprise diluting the solution of one selected from the group consisting of Pb(Zr,Ti)O₃, Bi(Fe,Mn,Ti)O₃, PbZrO₃, PbTiO₃, BiFeO₃ and doped-Pb(Zr,Ti)O₃ to 0.4 M with 1,3-propanediol or glycerol or ethyleneglycol, and mixture thereof, and depositing the diluted solution by inkjet printing on the seed layer.

Thickness ranges of the seed layer can be of from 10 nm and 100 nm, in various instances between 20 and 40 nm. The thickness ranges of the piezoelectric layer can be of from 10 nm and 5 µm, in various instances between 500 nm and 2 µm.

The invention also relates to a precursor solution of Pb(Zrₓ, Ti₁₋ₓ)O₃ for a seed layer of a piezoelectric film, the solution being prepared using 1-methoxy-2-propanol as a solvent and acetylacetone as a modifier.

The invention also relates to a microsystem obtained at least partly by the method discussed above. As exemplified below, analyses have shown that the microsystem is physically distinct from microsystem where other seed layer or no seed layer at all were used.

The particular but not exhaustive applications of the printing process of the invention are haptic devices on glass or microsystems (micro-mirrors, micro-switches, optical lenses).

The invention also relates to an use of a precursor solution of Pb(Zrₓ, Ti₁₋ₓ)O₃, where 0≤x≤1, using 1-methoxy-2-propanol as a solvent and acetylacetone as a modifier; and forming a seed layer for an electroactive film by spin coating the precursor solution on a substrate, for the preparation of a piezolectric layer onto the seed layer exhibiting an (100) orientation.

The invention also relates to a material deposition method comprising the steps of preparing a precursor solution of Pb(Zrₓ, Ti₁₋ₓ)O₃, where 0≤x≤1, using 1-methoxy-2-propanol as a solvent and acetylacetone as a modifier; and forming a seed layer for an electroactive film by spin coating the precursor solution on a substrate, further comprising the deposition onto the seed layer of a layer of one member selected from the group consisting of Pb(Zr,Ti)O₃, PbZrO₃, BaTiO₃, SrTiO₃, (Ba,Sr)TiO₃, Pb(Mg,Nb)-PbTiO₃, BiFeO₃ doped with La, Mn or Ti, (K,Na)NbO₃ PbTiO₃ and Pb(Zr,Ti)O₃doped with La, Mn or Nb or Pb(Sc,Ta)O₃., and, in some embodiments, mixture(s) thereof. The invention also relates to a material deposition method comprising the steps of: preparing a precursor solution of Pb(Zrₓ, Ti₁₋ₓ)O₃, where 0≤x≤1, using 1-methoxy-2-propanol as a solvent and acetylacetone as a modifier; and forming a seed layer for an electroactive film by spin coating the precursor solution on a substrate, further comprising preparing a solution of one selected from the group consisting of Pb(Zr,Ti)O₃, PbZrO₃, PbTiO₃ and doped-Pb(Zr,Ti)O₃, or mixture(s) thereof. The invention also relates to a material deposition method comprising the steps of: preparing a precursor solution of Pb(Zrₓ, Ti₁₋ₓ)O₃, where 0≤x≤1, using 1-methoxy-2-propanol as a solvent and acetylacetone as a modifier; and forming a seed layer for an electroactive film by spin coating the precursor solution on a substrate, further comprising preparing a solution of one selected from the group consisting of Pb(Zr,Ti)O₃, PbZrO₃, PbTiO₃ and doped-Pb(Zr,Ti)O₃.

This solution enables improving piezoelectric properties of the active layers on a piezoelectric microsystem. As the properties are enhanced, a thinner layer deposited according to the present invention can ensure the same functions as a thicker layer deposited with other methods. This means that the invention enables thinner layers to meet the required technical constraints. This simplifies the manufacturing of the layer and saves manufacturing time as well as the amount of material required.

The present invention proposes the only available solution to date to orient functional material in the preferential orientation 100 when inkjet printing or spin-coating piezoelectric material.

Finally, the use of 1-methoxy-2-propanol is beneficial to the environment and human health as 1-methoxy-2-propanol can degrade to lactate and pyruvate (through successively demethylase; alcohol dehydrogenase; aldehyde dehydrogenase and lactate dehydrogenase).

### DRAWINGS

FIG. 1 is a cross-section of a microsystem device, in accordance with various embodiments of the invention.

FIGS. 2 to 4 show comparative SEM images of a seed layer obtained with 2-methoxyethanol or 1-methoxy-2-propanol, with or without acetylacetone, in accordance with various embodiments of the invention.

FIG. 5 is an X-ray diffraction diagram comparison of a seed layer obtained with 1-methoxy-2-propanol or obtained with 2-methoxyethanol, in accordance with various embodiments of the invention.

FIG. 6 is similar to FIG. 5 but for seed layers obtained without acetylacetone, in accordance with various embodiments of the invention.

FIG. 7 is an X-ray diffraction diagram comparison of a spin-coated PZT film grown on a seed layer obtained with 1-methoxy-2-propanol or obtained with 2-methoxyethanol, in accordance with various embodiments of the invention.

FIG. 8 is an X-ray diffraction diagram comparison of an inkjet-printed PZT film grown on a seed layer obtained with 1-methoxy-2-propanol or obtained with 2-methoxyethanol, in accordance with various embodiments of the invention.

FIGS. 9, 10 and 11 are similar diagrams for respectively spin-coated BFO films on silicon substrate, PZO films on glass substrate (with Pt bottom electrode) and inkjet printed PZT on glass substrate, in accordance with various embodiments of the invention.

### DETAILED DESCRIPTION

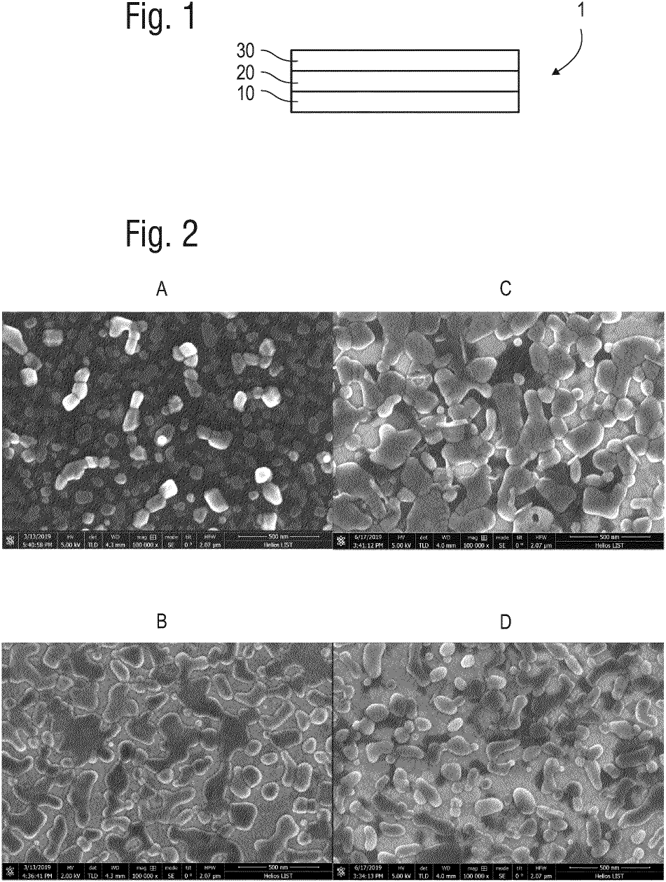

FIG. 1 shows a cross-section (not to scale) of a microsystem 1. A substrate 10 in various instances comprising a silicon base with a platinum coating is used. A seed layer 20 of PbTiO₃ (PTO) is deposited on the substrate 10. A functional material 30, made of Pb(Zr,Ti)O₃, Bi(Fe,Mn,Ti)O₃ or PbZrO₃, or BaTiO₃, or SrTiO₃, or (Ba,Sr)TiO₃ or Pb(Mg,Nb)-PbTiO₃ or BiFeO₃ or (K,Na)NbO₃ or PbTiO₃ or Pb(Zr,Ti)O₃ doped with La, Mn or Nb or Pb(Sc,Ta)O₃ is deposited on the seed layer 20.

Four comparative PTO precursor solutions were prepared (A, B, C, D), to highlight the effects of the solvent and modifier in the preparation of the PTO precursor.

| | | | | |
|---|---|---|---|---|
| solution | A | B | C | D |
| solvent | 1-methoxy-2-propanol | 2-methoxyethanol | 1-methoxy-2-propanol | 2-methoxyethanol |
| modifier | acetylacetone | acetylacetone | none | none |

For preparing 25 mL of PTO precursor solution A (with a concentration of Ti of 0.1 mol/L and with 30% excess lead), the following steps can be used: 0.733 g (2.5 mmol) of titanium(IV) isopropoxide (Ti(OiPr)₄) is dissolved in 25 mL of anhydrous 1-methoxy-2-propanol. Two mole-equivalents of acetylacetone (2,4-pentanedione) are added and the solution is stirred at room temperature for 15 min. Freeze-dried lead(II) acetate (Pb(CH₃CO₂)₂) is then added to this titanium solution. These steps are performed under inert atmosphere in a glove box. The container is then connected to a reflux apparatus under inert atmosphere. The solid lead precursor is dissolved at 80° C. After complete dissolution of the solid matter, the solution is refluxed for a duration of 2 hours under inert atmosphere. 50% of the solution volume is distilled off to eliminate reaction by-products. The solution is then diluted to 0.1 mol/L using anhydrous 1-methoxy-2-propanol.

The solvent 1-methoxy-2-propanol (propylene glycol methyl ether, PGME) can not be commercially available as anhydrous and can therefore be dried with 3 Å zeolite molecular sieves prior to use.

The final solution has a nominal concentration of 0.1 mol/L. Pb is present with a 30% excess to compensate for lead loss during the annealing process. Therefore, C_{Ti} = 0.1 mol/L and C_{Pb} = 0.13 mol/L.

Solution B is prepared in the same manner, except that 1-methoxy-2-propanol is replaced with 2-methoxyethanol.

Solutions C and D are prepared respectively in the same way as solutions A and B, except that no acetylacetone is introduced.

PTO solutions A to D are deposited on platinized silicon substrates by spin coating as follows: platinized silicon substrates (Si (bulk)/SiO₂ 500 nm/TiOₓ 20 nm/Pt 100 nm) are degassed on a hot plate at 350° C. for 5 min prior to deposition; then the PTO solution is spin-coated in a two-steps process: (1) rotating at 50 rpm for about 10 s (deposition of the solution through a 0.2 µm PTFE filter) and (2) rotating at between 3000 rpm and 4700 rpm for about 30 s (formation of the thin layer). The sample is then dried on a hot plate at 130° C. for 3 min, pyrolyzed on a hot plate at 350° C. for 3 min and finally crystallized in a rapid thermal annealing furnace at 700° C. for 1 min (ramp: 50° C./s) in air atmosphere.

FIG. 2 shows SEM images of the comparative results for the solutions A, B, C and D.

We can clearly observe the presence of nano-crystals on the seed layer prepared with solution A. The crystals are substantially less sharp with solution C and are absents with solutions B and D. As is supported by the X-ray diffraction graphs below, the presence of the nano-crystals constitutes a pre-crystallization that leads to an orientation (100) of the piezoelectric film.

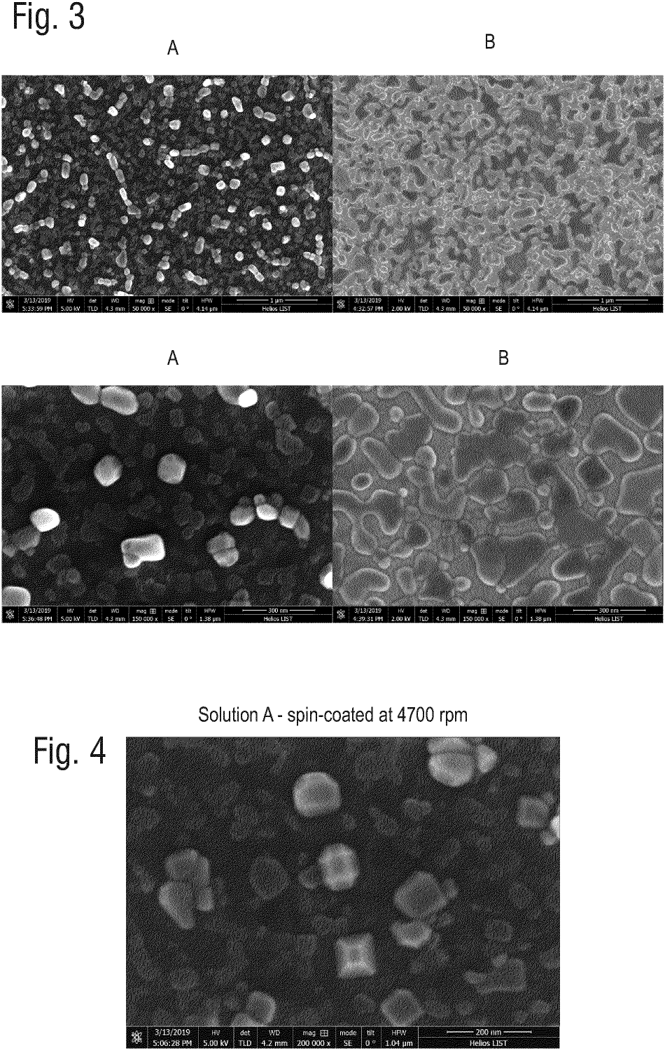

FIG. 3 highlights at two different scales the differences between a seed layer formed with solution A and with solution B.

FIG. 4 shows an example of a seed layer obtained by spin-coating the solution A at 4700 rpm (to be compared with FIGS. 2 and 3 where the coating is made at 3000 rpm). This figure proves that the speed of rotation used in the second step of spin-coating has little to no influence on the presence of nano-crystals. This constitutes further evidence of the predominance of the influence of the solvent on the resulting seed layer.

FIG. 5 is an X-ray diffraction diagram comparison of a seed layer obtained with solution A and with solution B. The difference at (100) and (200) is manifest and one can see that with solution A, a peak of intensity at (100) and a peak at (200) is present, whereas the seed layer made with solution B shows no such peak.

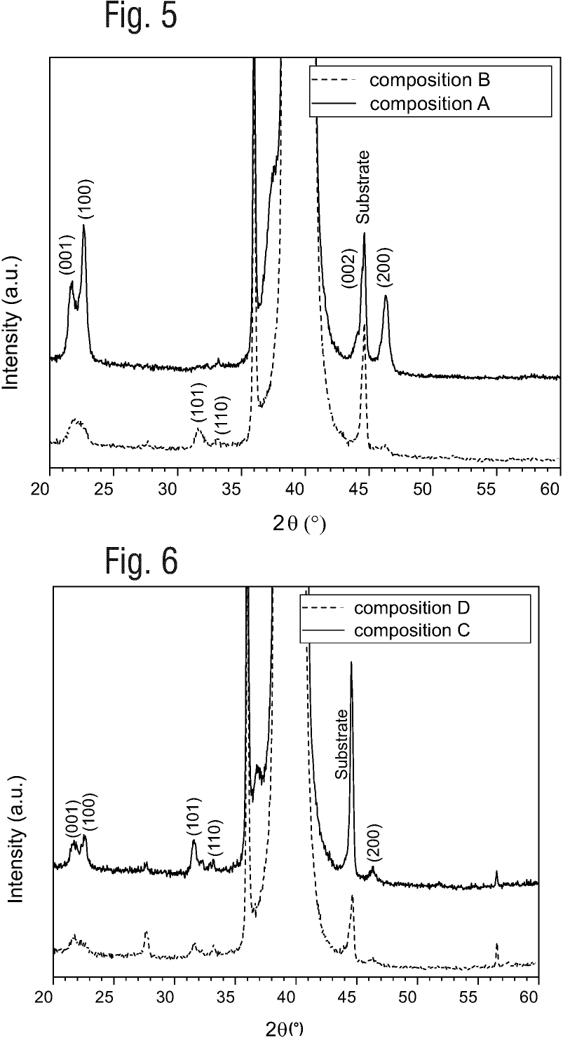

FIG. 6 is a similar diagram comparing seed layers obtained with solutions C and D (without acetylacetone). This shows that even without acetylacetone, the (100) and (200) peaks are higher with 1-methoxy-2-propanol than with 2-methoxyethanol. FIGS. 5 and 6 show that the best results are obtained with composition A, where 1-methoxy-2-propanol and acetylacetone operate in synergy.

Over the seed layer 20 is deposited a film of Pb(Zr,Ti)O₃ (PZT), Bi(Fe,Mn,Ti)O₃ (BFO) or PbZrO₃ (PZO). A detailed example is given hereinafter for the preparation of PZT and BFO solutions. Similar preparation can be done with PZO.

The preparation of the PZT solution can differ depending on the coating technique that is intended. We will firstly describe the preparation of PZT to be spin-coated on the seed layer and then the preparation of PZT to be inkjet printed on the seed layer.

The PZT solution for spin-coating is prepared according to a protocol that resembles the one described above for the PTO solution. The stoichiometry is such that Zr/Ti = 53/47 and Pb is present in 10% excess. The following procedure describes the preparation of 100 mL of PZT solution for spin coating.

Zirconium(IV) butoxide (80 wt% in butanol, 7.63 g, 15.9 mmol) is weighed inside a round bottom flask containing 20 mL of anhydrous solvent (2-methoxyethanol or 1-methoxy-2-propanol). Acetylacetone (99.5 %, 3.28 mL, 31.8 mmol) is added to the solution, which is gently stirred for 10 min. The same procedure is repeated in a separate flask containing 20 mL of solvent with titanium(IV) isopropoxide (97 %, 4.13 g, 14.1 mmol), to which acetylacetone (2.91 mL, 28.2 mmol) is also added. The two solutions are combined in the first flask and 10 mL of solvent are used to wash the flask containing the titanium precursor. Freeze-dried lead(II) acetate (99.5 %, 10.79 g, 33.0 mmol) is then added to the resulting mixture of alkoxides. All these operations are performed in a glovebox.

The flask is connected to a reflux apparatus under argon atmosphere. Lead(ll) acetate is dissolved at 80° C. under stirring (800 rpm). After complete dissolution of the solid material, the temperature of the oil bath is raised to 130° C. The stirring speed is decreased to 300 rpm at the moment of boiling. The solution is maintained at reflux for 2 h. The flask is then transferred to a distillation apparatus, where 50 mL of the solution are distilled off. The solution is finally diluted to 1 mol/L with solvent (V_{final} = 100 mL).

The PZT solution is further diluted with solvent to 0.3 mol/L. The solution is then spin-coated on the seed layer prepared as above (with 1-methoxy-2-propanol). The process involves 2 steps: (1) 50 rpm for about 10 s (deposition of the solution through a 0.2 µm PTFE filter) and (2) 3000 rpm for about 30 s (formation of the thin layer). The sample is then dried on a hot plate at 130° C. for 3 min, pyrolyzed on a hot plate at 350° C. for 3 min. This deposition procedure is performed 4 or 5 times for 1-methoxy-2-propanol or 2-methoxyethanol-based PZT solutions, respectively. The layer is finally crystallized in a rapid thermal annealing furnace at 700° C. for 5 min (ramp: 50° C./s) in air atmosphere. The result is a 200 nm-thick PZT film. The thickness of the layer can be increased by iteration of this process, i.e. to obtain micron-thick films, this whole process can be carried out successively 5 times.

As for the Mn and Ti co-doped BiFeO₃ thin films, these can be synthesized following a nitrate-based route. The precursor solution is prepared from Bi(NO₃)₃·5H₂O (≥ 98.0% Merck), Fe(NO₃)₃·9H2O (≥ 98.0% Merck) and Mn(NO₃)₃·4H₂O, (≥ 99.99% Merck). Titanium is introduced using a 0.1 mol/L precursor solution that is synthesized from titanium(IV) isopropoxide, acetylacetone and 2-methoxyethanol (2-MOE) as the solvent. The solution is prepared with a concentration of metal ions of 0.25 M, assuming that manganese and titanium are introduced in the Fe-site in the perovskite structure of BiFeO₃. The concentration of manganese and titanium is 5% and 2% respectively. A Bi-excess of 5% is used to compensate for bismuth losses. The salts are weighed and dissolved in 2-MOE. The water in the solution is removed using a stoichiometric amount of acetic anhydride, added dropwise to avoid excessive heating. During the reaction of acetic anhydride and water, acetic acid is produced, which can also act as a complexing agent for the metal ions.

The bismuth ferrite solution is spin coated at 3000 rpm on the seed layer. The sample is heated at 90° C. on a hot plate for gelation. Then, it is dried at 270° C. Pyrolysis at 450° C. and crystallization at 650° C. are performed using RTA under pure O₂ atmosphere. A layer with a thickness of 25 nm can be obtained at each deposition. The process can be repeated to obtain thicker films.

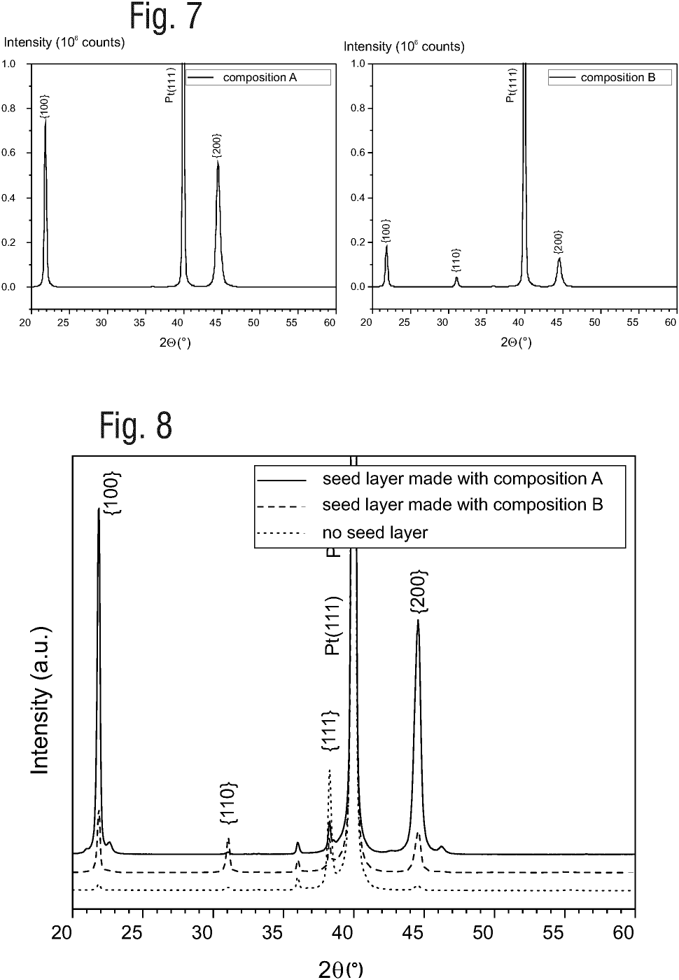

FIG. 7 shows a comparison of XRD diagrams for the same PZT solution spin-coated on a seed layer made with solution A or with solution B. One immediately notices that the PZT deposited on a seed layer made from A shows a peak that is four times more intense at orientation (100) than it is on a seed layer made from solution B. The diagram with solution A is also noticeably flat at (110). A pure (100) orientation of the PZT film is thus obtained. The peaks of sensibly similar intensity on both curves are the peaks that are representative of the substrate, which is similar in both cases.

The preparation of PZT for inkjet printing on the seed layer is substantially similar: A 1 mol/L PZT stock solution in 2-methoxyethanol is initially prepared according to the above-detailed protocol. This solution is then diluted down to 0.4 M with 1,3-propanediol or glycerol and ethyleneglycol. The solution is then injected into a Fujifilm DMCLCP-11610 cartridge through a 0.2 µm PTFE filter.

The ink thereby obtained is then deposited on the substrate with 15 µm and 254 µm droplet spacings along the x and y directions, respectively. After printing, the layer is dried at 175° C. for 1 min and pyrolyzed at 475° C. for 3 min. The printing-annealing cycle is performed 6 times in total, after which the resulting layer is crystallized in a rapid thermal annealing furnace at 700° C. for 5 min (ramp: 50° C./s) in air atmosphere. This results in a 200 nm-thick PZT film.

FIG. 8 shows a comparison of inkjet-printed films on three different substrates (one without seed layer, the two others with seed layer made from solution A or B). One can immediately see the peak at (100) and the absence of peak at (110) when solution A is employed.

The solvent used for preparing PZT has no noticeable influence on the orientation of the PZT film. As explained above, an appropriate solvent is used according to the desired deposition technique.

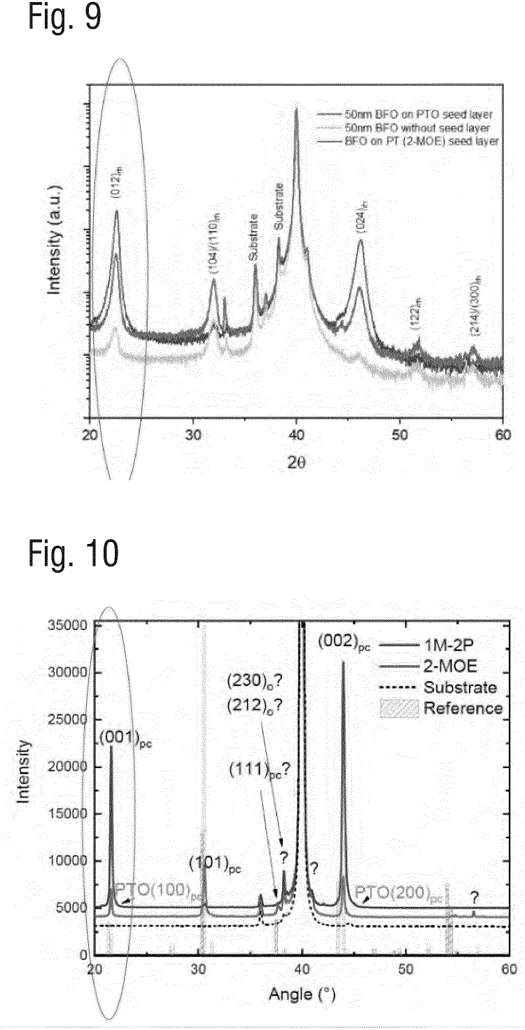

FIGS. 9 and 10 show XRD diagrams respectively of BFO and PZO. In both cases, the spin-coating deposition of BFO and PZO on a seed layer made from solution A presents a higher peak of intensity at (100) than the deposition of BFO or PZO on a seed layer made from solution B. Although a seed layer with solution B is better than no seed layer at all, these diagrams prove again that the seed layer with solution A (i.e. made with 1-methoxy-2-propanol rather than 2-methoxyethanol) shows a substantially better (100) orientation.

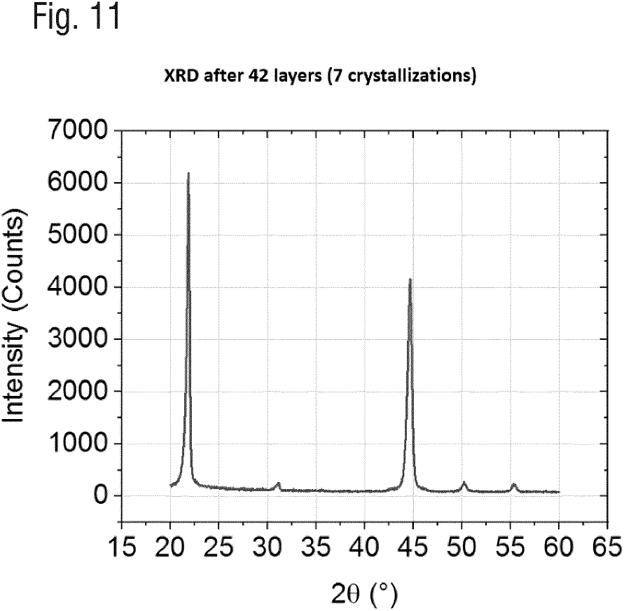

FIG. 11 shows the results obtained when printing PZT on a seed layer made from solution A, deposited on a glass substrate.

The exemplary embodiments presented above and the various quantities and numbers are given to illustrate the invention. The person skilled in the art would understand that the scope of the invention is only limited by the appended claims and that variation in the amount of dilution or the time duration for the various steps of the method do not depart from the scope of the present invention. For example, variations of about 10% to 20% in the dilution ratios, the duration of the steps, the temperatures or the speed of the spinner can be used.

1-17. (canceled)

18. A material deposition method, said method comprising the steps of:
preparing a precursor solution of Pb(Zrₓ, Ti₁₋ₓ)O₃,where 0≤x≤1, using 1-methoxy-2-propanol as a solvent and acetylacetone as a modifier;
forming a seed layer by spin coating the precursor solution on a substrate; and
further depositing a piezoelectric layer onto the seed layer.

19. The material deposition method according to claim 18, wherein the deposited piezoelectric layer is formed of a compound selected from the group consisting of at least one of Pb(Zr,Ti)O₃, PbZrO₃, BaTiO₃, SrTiO₃, (Ba,Sr)TiO₃, Pb(Mg,Nb)-PbTiO₃, BiFeO₃, (K,Na)NbO₃, PbTiO₃, Pb(Zr,Ti)O₃ doped with La, Mn or Nb and Pb(Sc,Ta)O₃.

20. The material deposition method according to claim 18, comprising, before depositing the piezoelectric layer, preparing a solution for the piezoelectric layer of perovskite structures compound, wherein the compound is selected from the group consisting of at least one of Pb(Zr,Ti)O₃, Bi(Fe,Mn,Ti)O₃, PbZrO₃, PbTiO₃ and doped-Pb(Zr,Ti)O₃.

21. The material deposition method according to claim 20, wherein the concentration of the solution is between 0.1 mol/L and 2 mol/L, the solvent being one of 1-methoxy-2-propanol and 2-methoxyethanol.

22. The material deposition method according to claim 20, wherein the step of depositing the piezoelectric layer comprises spin coating the solution on the seed layer.

23. The material deposition method according to claim 20, comprising diluting the solution for the piezoelectric layer to 0.4 M with 1,3-propanediol or glycerol and ethyleneglycol, and depositing the diluted solution by inkjet printing on the seed layer.

24. The material deposition method according to claim 18, comprising, before depositing the piezoelectric layer, preparing a solution for the piezoelectric layer of BiFeO₃, optionally doped with Mn and/or Fe, with a concentration between 0.1 mol/L and 2 mol/L, preferably 0.25 mol/L in a solvent of 1-methoxy-2-propanol or 2-methoxyethanol.

25. The material deposition method according to claim 24, comprising, before depositing the piezoelectric layer, preparing a solution for the piezoelectric layer of BiFeO₃, optionally doped with Mn and/or Fe, with a concentration of 0.25 mol/L in a solvent of 1-methoxy-2-propanol or 2-methoxyethanol.

26. The material deposition method according to claim 24, wherein the step of depositing the piezoelectric layer comprises spin coating the solution of BiFeO₃ on the seed layer.

27. The material deposition method according to claim 18, wherein x=0.

28. The material deposition method according to claim 18, wherein, for preparing the precursor, at least one of the following steps are performed:
dissolving titanium(IV) isopropoxide in anhydrous 1-methoxy-2-propanol;
adding acetylacetone to Ti precursor;
stirring this titanium solution;
adding freeze-dried lead(II) acetate;
heating for dissolving lead(II) acetate;
refluxing and optionally distilling; and
diluting to 0.1 mol/L +/- 0.05 mol/L using anhydrous 1-methoxy-2-propanol.

29. The material deposition method according to claim 18, wherein 1 -methoxy-2-propanol is dried with 3 Å zeolite molecular sieves prior to use.

30. The material deposition method according to claim 18, wherein the step of spin coating the seed layer comprises:
spin coating at a first rotational speed for a first duration; and
subsequently, spin coating at a second rotational speed, greater than the first speed, for a second duration, longer than the first duration.

31. The material deposition method according to claim 18, wherein after depositing the seed layer, the seed layer is dried, pyrolyzed and crystallized.

32. The material deposition method according to claim 18, wherein the substrate is made of platinized silicon or of glass.

33. A precursor solution of Pb(Zrₓ,Ti₁₋ₓ₎O₃ for a seed layer of a piezoelectric film, the solution being prepared using 1-methoxy-2-propanol as a solvent and acetylacetone as a modifier.

34. A microsystem obtained at least partly by preparing a precursor solution of Pb(Zrₓ, Ti₁₋ₓ)O₃, where 0≤x≤1, using 1-methoxy-2-propanol as a solvent and acetylacetone as a modifier; forming a seed layer by spin coating the precursor solution on a substrate; and further depositing a piezoelectric layer onto the seed layer.
